(19) United States
(12) Patent Application Publication
(10) Pub. No.: US 2003/0104687 A1
(43) Pub. Date: Jun. 5, 2003

(54) Temporary chip attach structure with thin films

(75) Inventors: Enrique C. Abreu, Mayaguez, PR (US); Rmar M. Ahmad, Hopewell Junction, NY (US); Gregory M. Johnson, Poughkeepsie, NY (US); Robert W. Pasco, Wappingers Falls, NY (US); Chase R. Perry, Wappingers Falls, NY (US); Brenda Peterson, Wappingers Falls, NY (US)

Correspondence Address: INTERNATIONAL BUSINESS MACHINES CORPORATION, DEPT. 18G, BLDG. 300-482, 2070 ROUTE 52, HOPEWELL JUNCTION, NY, 12533, US

(73) Assignee: INTERNATIONAL BUSINESS MACHINES CORPORATION, ARMONK, NY

(21) Appl. No.: 10/007,097

(22) Filed: Dec. 4, 2001

(51) Int. Cl. H01L 23/053; H01L 29/40; H01L 21/44

(52) U.S. Cl. 438/613; 257/700; 257/779

(57) ABSTRACT

A temporary chip attach (TCA) structure is made with two layers of thin films. The first layer contains capture pads to capture the positional error of the underlying chip carrier vias. The second layer contains smaller TCA pads of exposed metal which are accurately aligned to the grid of the chip BLM, as well as appropriate alignment features for use by a chip automatic placement tool.

### FIELD OF THE INVENTION

The present invention relates to a structure for temporarily connecting two elements or surfaces with two layers of thin film metallurgy. More particularly, the present invention relates to a structure for temporarily attaching an integrated circuit chip to a chip carrier for test burn-in purposes, which comprises two layers of thin film metallurgy and overcomes problems of electrical test yield, high stress chip shear removal and automated chip placement.

### BACKGROUND OF THE INVENTION

As semiconductor devices become smaller and more dense there has been a corresponding increase in overall chip failure rates. This creates a need to be able to identify and eliminate defective chips before they are permanently attached to product. It is therefore desirable to temporarily attach the chip to a chip carrier in such a way that the chip can be separated after test without mechanical damage to either the chip or the chip carrier. Burn-in test processes have been developed in order to identify and eliminate the use of defective chips. The burn-in test process operates the chip at elevated voltage and temperature levels for an extended period of time in order to simulate the actual operation of the chip for its normal and expected lifetime in a product.

A chip carrier is provided for testing the chip which has electrical contacts which correspond to the electrical contacts on the chip. Typically the chip is positioned on the chip carrier so that the solder balls on the chip are aligned with the corresponding electrical contacts on the chip carrier. The solder balls on the chip are partially reflowed to make electrical connections between the chip and the chip carrier. This is preferably a mechanically weak connection so as to facilitate removal of the chip from the chip carrier by a shear process after burn-in test. This allows defective chips to be screened and good chips, commonly referred to as known good die (KGD), to be subsequently attached permanently to product. The chip carrier can then be re-used for testing of additional chips.

The Temporary Chip Attach (TCA) structure therefore allows the use of only Known Good Die (KGD) on the product. A number of methods have been devised and described by others to form a temporary connection between semiconductor chips and chip carriers, so as to be able to separate the chip from the chip carrier for subsequent permanent chip attach.

Beaumont et al. U.S. Pat. No. 5,494,856, the disclosure of which is incorporated by reference herein, describes a method for creating solder connections between two surfaces which connections are relatively weak and can be readily fractured for separating surfaces.

Referring to FIG. 1 there is shown a schematic cross section view of a conventional TCA structure. A chip carrier 10 is provided with electrical connections, in this example a multilayer ceramic substrate with molybdenum via interconnections 20. Using standard photolithographic techniques well known in the art a thin film dielectric layer (not shown) is formed on the top surface of the chip carrier 10 which contains small openings positioned over and contained within the molybdenum via 20. A conventional nickel plating process is then performed and the dielectric layer removed. This plating step results in nickel temporary chip attach pads 30 formed on the surface of the molybdenum vias 20. The chip 50 is temporarily attached by a conventional solder bump 40 joining process to the chip carrier 10 for burn-in test. The small wettable area provided by the temporary chip attach pad 30 allows removal of the chip by a shear operation.

Referring again to FIG. 1, it can be seen that during chip attach the solder bump 40 will only wet to the small area of the temporary chip attach pad 30. This reduced area of contact between the chip carrier 10 and solder ball 40 of the chip 50 reduces the shear force required to separate the chip 50 from the chip carrier 10 after burn-in test. This minimizes the damage to the chip 50 allowing for subsequent permanent attachment of the chip to product.

Referring to FIG. 2 there is shown a top view of the conventional temporary chip attach carrier 10 of FIG. 1. For simplicity only a 4×4 array of interconnect vias 20 are shown, but it will be understood by those skilled in the art that a typical chip carrier could have thousands of such vias. It is shown that in the conventional TCA structure the temporary chip attach pads 30 are rectangular and aligned in a radial arrangement or orientation on the chip carrier 10 in order to compensate for the radial distortion of the molybdenum vias 20. In a typical conventional TCA structure the nickel temporary chip attach pads 30 are 0.0014×0.002 inches in size and approximately 2 to 4 μm thick. This radial distribution of alignment of the temporary chip attach pads 30 prevents further reduction in contact area of the temporary chip attach pad 30 and thus prevents further reduction in shear stress.

Referring again to FIG. 1 the temporary chip attach pads 30 are placed on a perfect grid (12 μm placement accuracy) which corresponds to the grid of the chip solder balls 40. However due to substrate distortion, which occurs during the firing process used in producing the ceramic substrate, the molybdenum vias 20 have a positional error or deviation from their ideal position. This is typically a radial distortion. This distortion or positional error causes the temporary chip attach pads 30 to be offset from the center of the molybdenum vias 20.

Referring to FIG. 3, a top view of the chip carrier 10, the ideal design position of the molybdenum via 20 and the actual post fired position of the molybdenum via 22 are shown to illustrate the effect of the via distortion on the alignment of the temporary chip attach pad 30.

There are several problems with the current TCA structure. One problem is that the current shear stress created when the chip is removed from the temporary chip carrier may approach undesirable levels with future generations of finer pitch solder balls. The current process for chip removal after burn-in test is a cold shear. The current structure places up to 9 grams per solder ball of force on the solder interface between the chip and chip carrier. This can be reduced by further decreasing the contact area of the temporary chip attach pads. However reducing the size of the temporary chip attach pads exacerbates another problem with the current TCA structure which is burn-in test yield loss. Yield loss during test burn-in is a consequence of the chip solder balls being misaligned to the temporary chip attach pads during the chip automated placement process. Because of the poor contrast in color between the grey nickel temporary chip attach pad and the grey molybdenum via the chip automated placement tool aligns the chip solder balls to the center of the molybdenum vias which may have a positional error as discussed above. The current TCA structure does not provide alignment features which are aligned to the grid of the temporary chip attach pads. Since the temporary chip attach pads are placed on the molybdenum vias by a photomask process their grid is an accurate match to the grid of the chip solder bumps. Therefore the distortion of the molybdenum vias of the chip carrier will prevent the temporary chip attach pads from being centered on the molybdenum vias.

Another problem with the current TCA structure is that the poor contrast in color between the grey nickel temporary chip attach pad and the grey molybdenum via requires occasional manual alignment on the automated chip placement tool resulting in increased process time.

The current solutions to these problems have not been adequate. The current solution to the problem involves reducing the size of the temporary chip attach pad. In the current TCA structure, a temporary chip attach pad or “nickel window” approximately 0.0014×0.002 inches is plated on top of a molybdenum via. The current solution reduced the area of contact of the chip solder ball with the TCA carrier thereby reducing the shear force. However, the current solution also reduced the electrical yield of the chip burn-in test. The reduced temporary chip attach pad size further exacerbated the problem of the chip solder bumps being aligned improperly to the temporary chip attach pads during the chip automated placement.

In addition to the current problems new chip technologies will involve finer pitch solder connections and more delicate structures added to the ball limiting metallurgy (BLM) of the chips to accommodate the demands of more advanced groundrules. This creates a need for a TCA structure that provides both lower shear stress chip removal and higher electrical yield. Furthermore, as chip density increases and chip BLM diameters decrease there will be a need for smaller temporary chip attach pads just to maintain the current shear stress levels.

Reding et al. U.S. Pat. No. 4,772,936, the disclosure of which is incorporated by reference herein, discloses a flexible tape structure having a metal pattern on both sides for testing integrated circuit devices prior to the packaging operation. The invention requires “flip-chip” bonding techniques together with a TAB (Tape Automated Bonding) mounting system. The invention does not provide for accommodation of pattern distortion and TCA shear would not be possible using this structure.

Perfecto et al. U.S. Pat. No. 5,916,451, the disclosure of which is incorporated by reference herein, relates to the application of minimal size capture pads to misaligned ceramic vias. The disclosed method requires the mapping of the actual location of the ceramic vias. The substrate-specific information about the ceramic via positional error is required to establish a unique mask or capture pad arrangement for each individual substrate. This is in contrast to the present invention which does not require any mapping. The present invention does not require the mapping of any specific information about the individual substrates.

Magill et al. U.S. Pat. No. 5,315,485, the disclosure of which is incorporated by reference herein, employs capture pads of variable size to accommodate the actual distortion of a given substrate. The reference does not teach the use of a second layer of capture pads with reduced size to minimize the contact area between the capture pad and chip BLM.

Notwithstanding the prior art solutions to the problems, there remains a need for reduced shear stress during chip removal and improved test yields.

Accordingly, it is a purpose of the present invention to provide a temporary chip attach structure with reduced contact area between the chip and the chip carrier in order to reduce the shear stress during chip removal.

It is another purpose of the present invention to provide a temporary chip attach structure with improved alignment between the chip and chip carrier and with chip alignment features to facilitate the use of an automated chip placement tool.

These and other purposes of the present invention will become more apparent after referring to the following description considered in conjunction with the accompanying drawings.

### BRIEF SUMMARY OF THE INVENTION

The purposes and advantages of the present invention have been achieved by providing a temporary chip attach structure comprising a chip carrier having surface electrical connection features, a first dielectric layer formed upon a surface of the chip carrier, the first dielectric layer having capture pads contiguous with at least a portion of the surface electrical connection features, and a second dielectric layer formed upon the first dielectric layer, the second dielectric layer having temporary chip attach pads contiguous with at least a portion of the capture pads. In a preferred embodiment the second dielectric layer contains alignment features to facilitate automated chip placement.

In one embodiment the chip carrier is a multilayer ceramic substrate, preferably alumina with molybdenum vias or glass ceramic with copper vias.

The first dielectric layer is preferably polyimide. In one embodiment the capture pads comprise a first layer of chrome and a second layer of copper. In another embodiment the capture pads comprise a first layer of chrome and a second layer of nickel. The capture pads may have a circular, square or rectangular shape. In one embodiment the capture pads are rectangular in shape and are radially oriented toward the center of the chip carrier.

The second dielectric layer is preferably polyimide. In one embodiment the temporary chip attach pads are nickel. In another embodiment the temporary chip attach pads are copper.

In another embodiment the temporary chip attach structure has a second temporary chip attach pad formed upon the first temporary chip attach pad. In a preferred embodiment the second temporary chip attach pad is nickel.

### BRIEF DESCRIPTION OF THE DRAWINGS

The features of the invention believed to be novel and the elements characteristic of the invention are set forth with particularity in the appended claims. The Figures are for illustration purposes only and are not drawn to scale. The invention itself, however, both as to organization and method of operation, may best be understood by reference to the detailed description which follows in conjunction with the accompanying drawings in which:

FIG. 1 is a schematic cross section view of a current TCA structure according to the prior art.

FIG. 2 is a schematic top view of the current TCA structure according to the prior art.

FIG. 3 is a schematic top view of the current TCA structure illustrating the effect of via distortion according to the prior art.

FIG. 4 is a schematic cross section view of a TCA structure according to the present invention.

FIG. 5 is a schematic top view of the first thin film layer according to the present invention.

FIG. 6 is a schematic top view of the second thin film layer according to the present invention.

FIG. 7 is a schematic cross section view of a TCA structure having a second temporary chip attach pad according to the present invention.

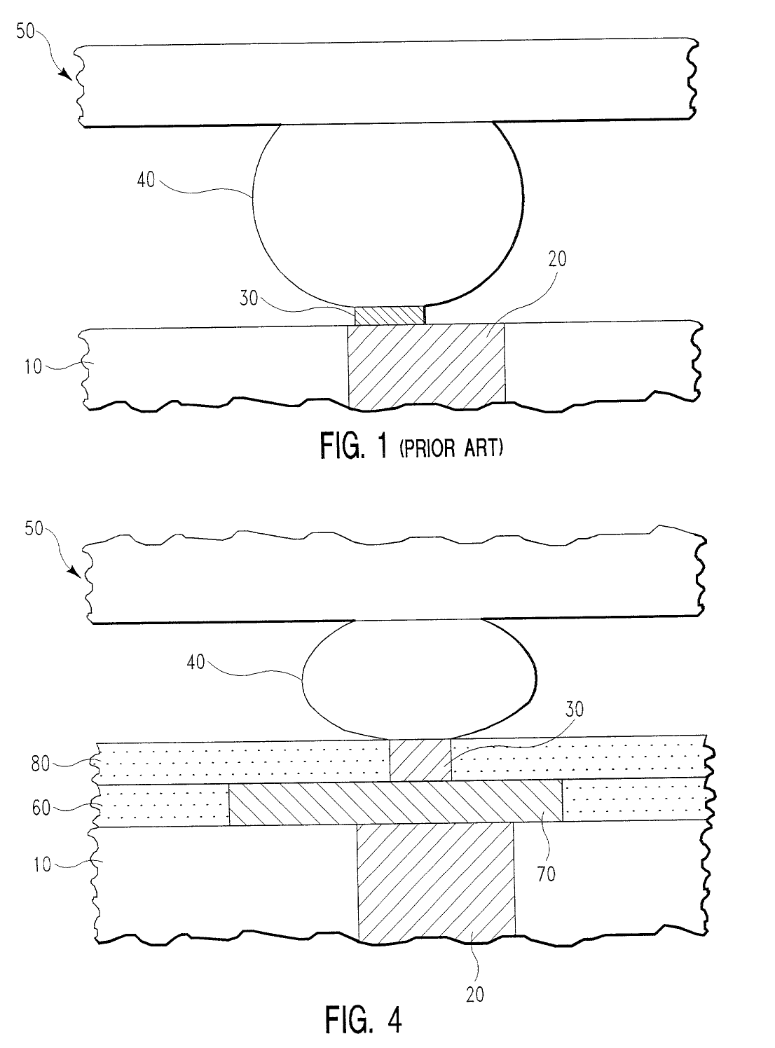

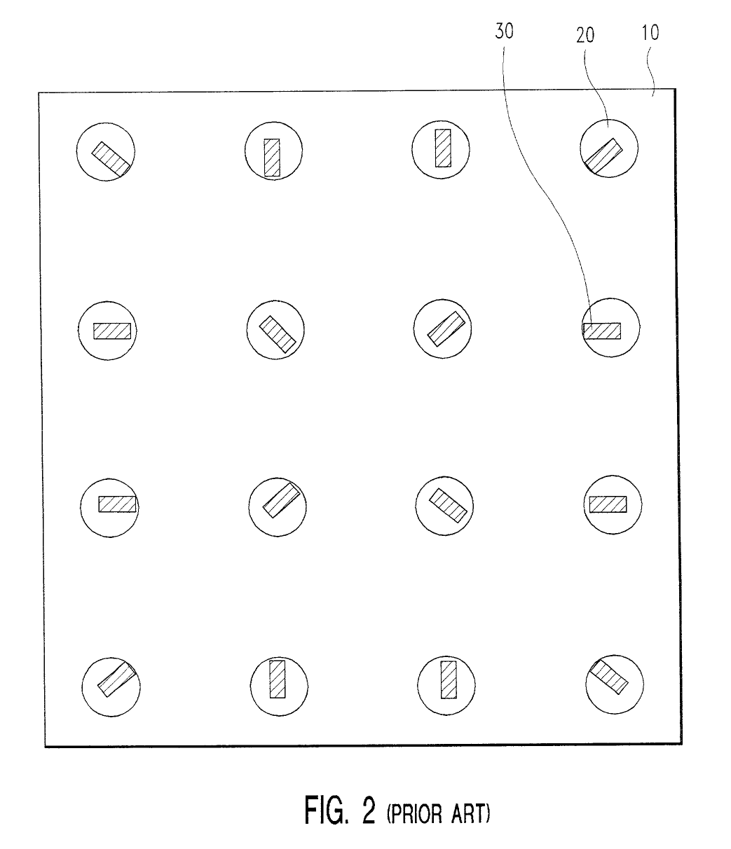

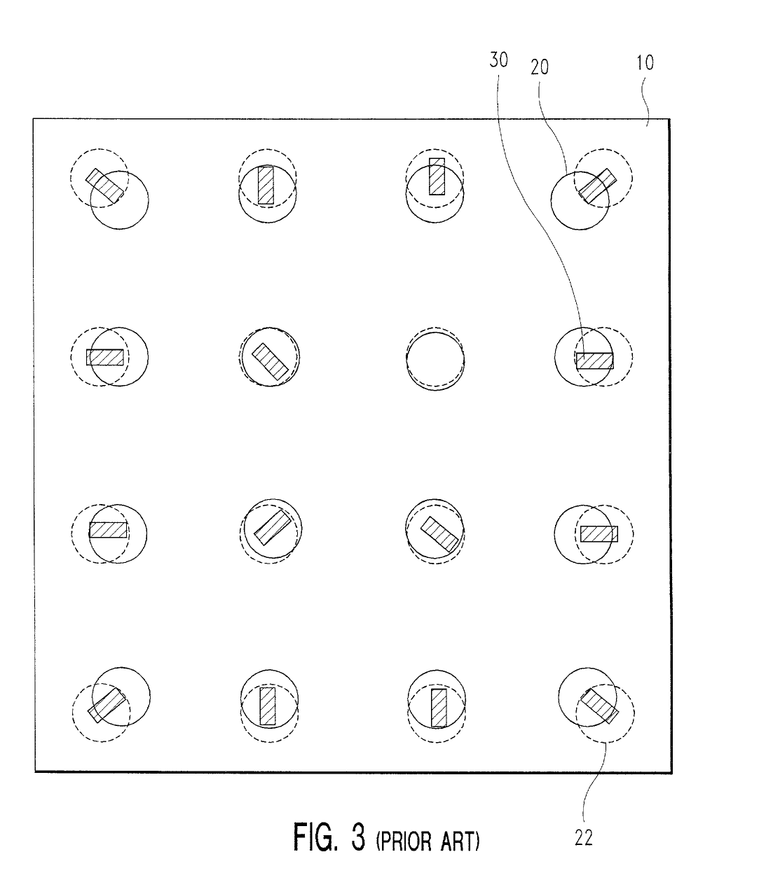

### DETAILED DESCRIPTION OF THE INVENTION

Referring to FIG. 4 there is shown a schematic cross section of a TCA structure according to the present invention. The TCA structure comprises a chip carrier 10. In this example the chip carrier 10 is a multi-layer ceramic substrate with molybdenum via interconnections 20. A typical molybdenum via is approximately 0.004 inches in diameter. The substrate may be planarized or polished as needed for process optimization.

A first thin film dielectric layer 60 is formed over the surface of the chip carrier 10. The first thin film dielectric layer 60 is preferably a polyimide deposited by standard spin techniques well known in the art. The thickness of the first thin film dielectric layer 60 is preferably 5 to 15 μm. The first thin film dielectric layer 60 contains capture pads 70 to capture the molybdenum via interconnections 20. The capture pads 70 are formed in the first dielectric layer 60 using standard lithography techniques to expose the desired capture pad pattern and then wet develop and etch the capture pad openings. Alternatively a laser could be used to form the capture pad openings.

The capture pad openings in the first thin film dielectric layer 60 are then filled with the desired metallurgy to form the capture pads 70. This may be accomplished by standard evaporation or sputtering techniques. The capture pads 70 are preferably composed of a first layer of chrome, a few hundred angstroms thick, and a second layer of copper, approximately 0.5 to 1.0 μm thick. In another embodiment the capture pads 70 are composed of a first layer of chrome, a few hundred angstroms thick, and a second layer of nickel, approximately 0.5 to 1.0 μm thick. The size and shape of the capture pads 70 are tailored to accommodate the positional error of the underlying chip carrier surface electrical connections.

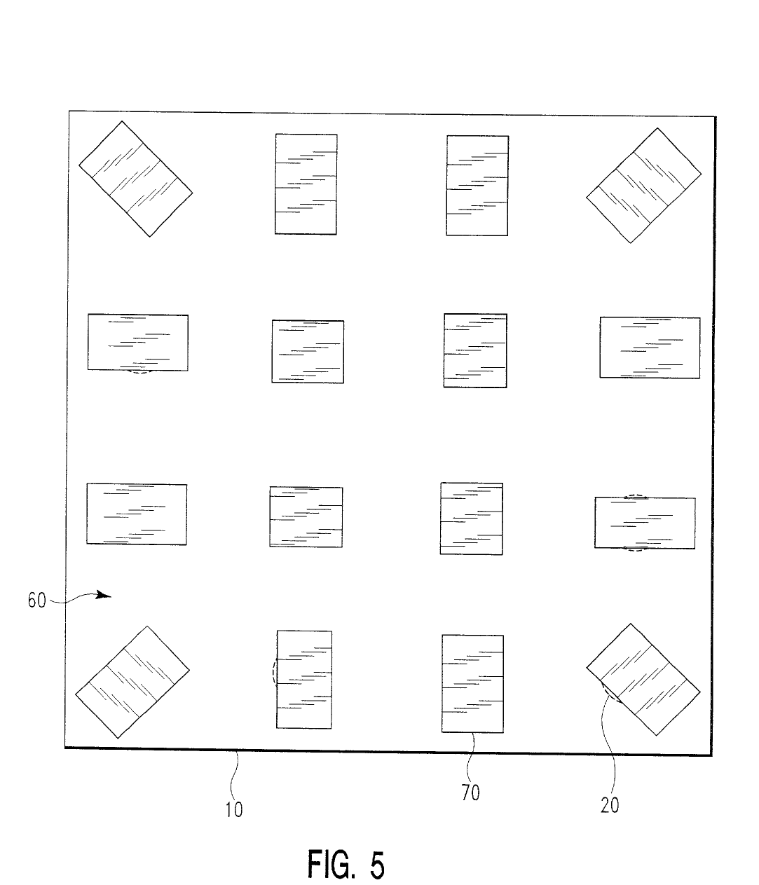

Referring to FIG. 5 there is shown a top schematic view of the chip carrier 10 showing the first dielectric layer 60. In this particular embodiment the capture pads 70 are rectangular. The capture pads 70 can extend beyond the diameter of the via interconnections 20 and can therefore accommodate the distortion or positional error of the underlying via interconnections 20. The via interconnections 20 are represented by dashed circles since they are covered by the overlying capture pad 70 or the overlying dielectric layer 60. It is not necessary that the entire via 20 be encompassed by the capture pad 70.

The capture pads 70 may also be circular, square, or any customized shape tailored to accommodate the positional error of the via interconnections 20 and provide electrical contact between the capture pad 70 and interconnect via 20. In the particular embodiment illustrated in FIG. 5 the rectangular capture pads 70 are radially oriented toward the center of the chip carrier to best accommodate this particular characteristic distortion. It would be apparent to those skilled in the art that other variations in the grid or pitch of the capture pads 70 would be suited to accommodate other characteristic distortion patterns and would be within the scope of the present invention.

Referring again to FIG. 4, a second thin film dielectric layer 80 is formed over the first thin film dielectric layer 60. The second thin film dielectric layer 80, preferably a polyimide, is deposited by standard spin techniques well known in the art. The thickness of the second thin film dielectric layer 80 is preferably 5 to 15 μm. The second thin film dielectric layer 80 contains temporary chip attach pads 30 which electrically contact the underlying capture pads 70. The temporary chip attach pads 30 are formed in the second dielectric layer 80 using standard lithography techniques to expose the desired temporary chip attach pad pattern and then wet develop and etch the temporary chip attach pad openings. Alternatively a laser could be used to form the temporary chip attach pad openings.

The temporary chip attach pad openings in the second thin film dielectric layer 80 are then filled with the desired metallurgy to form the temporary chip attach pads 30. This may be accomplished by standard evaporation or sputtering techniques. Alternatively, the temporary chip attach pads 30 could be plated. The temporary chip attach pads 30 are preferably composed of nickel or copper. The size and shape of the temporary chip attach pads 30 are tailored to reduce the contact area between the temporary chip attach pad 30 and the chip solder ball 40. This will reduce the shear stress created when the chip 50 is separated from the chip carrier 10 after test burn-in. In a preferred embodiment the temporary chip attach pads 30 are approximately 10% of the area of the capture pads 70.

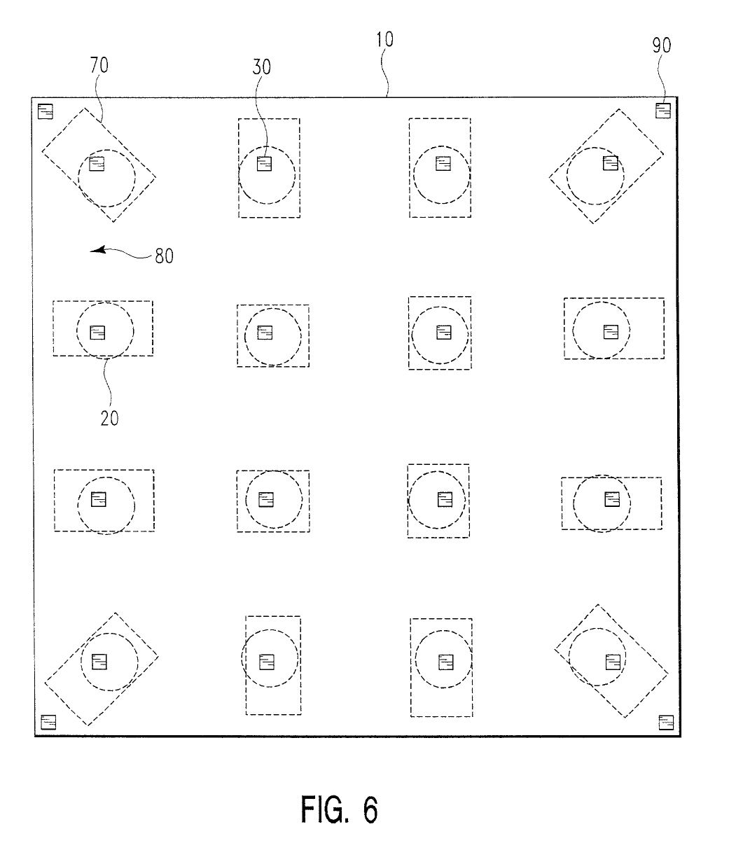

Referring to FIG. 6 there is shown a top schematic view of the chip carrier 10 showing the second dielectric layer 80. In this particular embodiment the temporary chip attach pads 30 are square. The temporary chip attach pads 30 may also be circular, rectangular, or any customized shape tailored to reduce the contact area between the chip solder ball (not shown) and the temporary chip attach pad and also provide electrical contact between the capture pad 70 and the temporary chip attach pad 30. The temporary chip attach pads 30 are accurately aligned to the grid of the chip solder bumps (not shown). The capture pads 70 are represented by dashed rectangles since they are covered by the temporary chip attach pad 30 or the overlying second dielectric layer 80.

Referring again to FIG. 6, the second thin film dielectric layer 80 may also contain a second set of alignment features 90 which are to be used by an automated chip placement tool. These alignment features 90 are preferably created simultaneously with the temporary chip attach pads 30. The alignment features 90 are positioned so as to align the chip to be tested to the temporary chip attach pads. This facilitates accurate alignment of the chip to the temporary chip attach pads 30.

This inventive TCA structure has several advantages over the conventional TCA structure. The first dielectric thin film layer allows for ample distortion of the chip carrier via grid since the capture pads may be larger than the vias. This is in contrast to the conventional nickel plated temporary chip attach pads which must be located within the via. Another benefit is that the greater tolerance for via distortion will increase the yield and reduce the cost of the chip carrier.

The second thin film dielectric layer allows for temporary chip attach pads of any size thereby providing the flexibility to tailor the pad size to reduce the shear stress. The second thin film dielectric layer also allows for alignment features to facilitate alignment of the chip to the temporary chip attach pads and thereby improve burn-in test yields. The improved alignment of the temporary chip attach pads to the chip solder bumps will enable further reductions in the temporary chip pad size thereby further reducing the chip removal shear stress.

Another benefit is that the use of copper temporary chip attach pads will improve the capability of the automated chip placement tools to distinguish the temporary chip attach pad and thereby reduce cycle time by reducing the need for manual alignment.

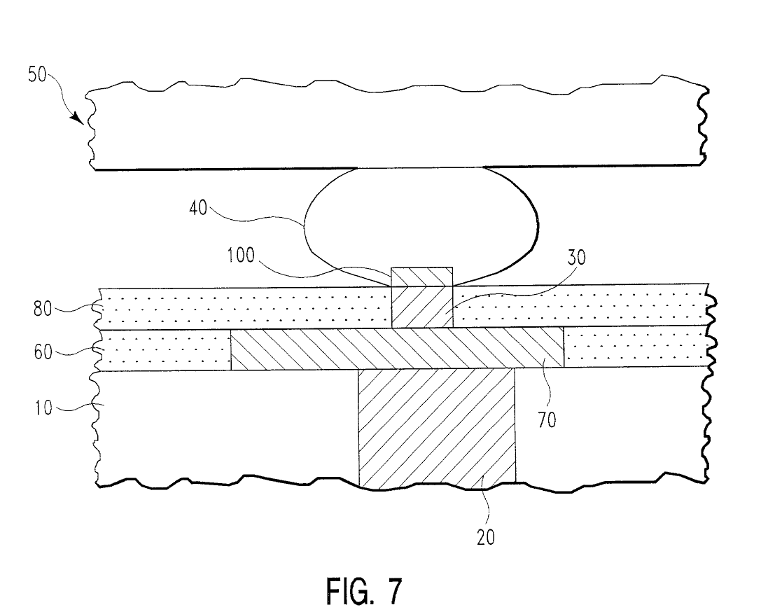

Referring to FIG. 7 there is shown a schematic cross section of another embodiment of the temporary chip attach structure. A second temporary chip attach pad 100 is formed upon the first temporary chip attach pad 30. The second temporary chip attach pad 100 can be formed from a conventional plating process. In a preferred embodiment the second temporary chip attach pad 100 is Nickel. Alternatively, the second temporary chip attach pad 100 could be formed by a conventional thin film process, such as that used to form the first temporary chip attach pad 30, followed by an etch to remove the dielectric surrounding the second temporary chip attach pad 100.

The second temporary chip attach pad 100 is approximately 1 to 10 μm in height and preferably 5 μm in height. The second temporary chip attach pad 100, being elevated above the second dielectric layer 80, will be easier to join to the chip 50. The elevated second temporary chip attach pad 100 will provide an anchor for the malleable solder ball 40. This will afford the opportunity to further reduce the area of the second temporary chip attach pad 100 and thereby further reduce the chip removal stress.

It will be apparent to those skilled in the art having regard to this disclosure that other modifications of this invention beyond those embodiments specifically described here may be made without departing from the spirit of the invention. Accordingly, such modifications are considered within the scope of the invention as limited solely by the appended claims.

What is claimed is:

1. A temporary chip attach structure, comprising:
a chip carrier having a plurality of surface electrical connection features;
a first dielectric layer formed upon a surface of said chip carrier, said first dielectric layer having at least one capture pad contiguous with at least one of said plurality of said surface electrical connection features; and,
a second dielectric layer formed upon said first dielectric layer, said second dielectric layer having at least one temporary chip attach pad contiguous with at least a portion of said at least one capture pad wherein, in operation, a chip is attached to the temporary chip attach pad for testing and is subsequently removed from the temporary chip attach pad after testing.

2. The temporary chip attach structure of claim 1 wherein said chip carrier is a multi-layer ceramic substrate.

3. The temporary chip attach structure of claim 2 wherein said surface electrical connection features are vias.

4. The temporary chip attach structure of claim 1 wherein said first dielectric layer is polyimide.

5. The temporary chip attach structure of claim 1 wherein said at least one capture pad comprises a first layer of chrome and a second layer of copper.

6. The temporary chip attach structure of claim 1 wherein said at least one capture pad comprises a first layer of chrome and a second layer of nickel.

7. The temporary chip attach structure of claim 1 wherein said at least one capture pad has a circular shape.

8. The temporary chip attach structure of claim 1 wherein said at least one capture pad has a rectangular shape.

9. The temporary chip attach structure of claim 1 wherein said at least one capture pad has a square shape.

10. The temporary chip attach structure of claim 8 wherein said at least one capture pad is radially oriented toward the center of the said surface of said chip carrier.

11. The temporary chip attach structure of claim 1 wherein said second dielectric layer is polyimide.

12. The temporary chip attach structure of claim 1 wherein said at least one temporary chip attach pad is nickel.

13. The temporary chip attach structure of claim 1 wherein said at least one temporary chip attach pad is copper.

14. The temporary chip attach structure of claim 1 wherein said at least one temporary chip attach pad is approximately 10% of the area of said capture pad.

15. The temporary chip attach structure of claim 1 wherein said second dielectric layer further comprises at least one alignment feature which is positioned so as to align the chip to be tested to the temporary chip attach pads.

16. The temporary chip attach structure of claim 1 further comprising a second temporary chip attach pad formed upon said temporary chip attach pad.

17. The temporary chip attach structure of claim 2 wherein said multi-layer ceramic substrate is alumina.

18. The temporary chip attach structure of claim 2 wherein said multi-layer ceramic substrate is glass-ceramic.

19. The temporary chip attach structure of claim 17 wherein said vias are molybdenum.

20. The temporary chip attach structure of claim 18 wherein said vias are copper.
